(19) United States
(12) Patent Application Publication
(10) Pub. No.: US 2003/0134476 A1
(43) Pub. Date: Jul. 17, 2003

(54) Oxide-nitride-oxide structure

(76) Inventors: Yakov Roizin, Afula (IL); Boaz Eitan, Ra'anana (IL)

Correspondence Address: Eitan, Pearl, Latzer & Cohen-Zedek, One Crystal Park, Suite 210, 2011 Crystal Drive, Arlington, VA, 22202-3709, US

(21) Appl. No.: 10/046,915

(22) Filed: Jan. 17, 2002

(51) Int. Cl. H01L 21/336

(52) U.S. Cl. 438/261

(57) ABSTRACT

A method for forming a non-volatile memory device, the method including forming an oxide-nitride-oxide (ONO) layer over a portion of a substrate, the ONO layer including a bottom oxide layer, a top oxide layer and a nitride layer intermediate the bottom and top oxide layers, and managing movement of at least one of electrons and holes from the substrate towards the ONO layer by controlling a thickness of at least one of the bottom oxide layer, the nitride layer and the top oxide layer, wherein the top oxide layer is at least 1.5 times thicker than the bottom oxide layer. Non-volatile memory devices constructed in accordance with methods of the invention are also described.

### FIELD OF THE INVENTION

The present invention relates to non-volatile memory cells in general, and particularly to an oxide-nitride-oxide (ONO) structure for improved performance of non-volatile memory cells with non-conducting charge trapping layers.

### BACKGROUND OF THE INVENTION

Nitride, programmable read only memory (NROM) cells comprise an oxide-nitride-oxide (ONO) charge-trapping layer. FIG. 1 illustrates a typical structure of an NROM non-volatile memory device.

NROM device 10 preferably includes a channel 12 formed in a substrate 14. Two diffusion areas 16 and 18 are preferably formed on either side of channel 12 in substrate 14, each diffusion area having a junction with channel 12. An oxide-nitride-oxide (ONO) layer 20 (i.e., a sandwich of a bottom oxide layer 20A, a nitride layer 20B and a top oxide layer 20C) is preferably formed at least over channel 12, and a polysilicon gate 22 is preferably formed at least over ONO layer 20. NROM device 10 may comprise two separated and separately chargeable areas 23A and 23B in the nitride layer 20B, each chargeable area defining and storing one bit. One of the diffusion areas 16 and 18 serves as the drain, while the other serves as the source. In an array of NROM cells, the drain and source may be connected to bit lines (not shown) and the gate may be connected to a word line (not shown).

In the prior art, bottom oxide layer 20A is typically about 7 nm thick, nitride layer 20B is typically about 5 nm thick, and top oxide layer 20C is typically about 9 nm thick. Accordingly, the overall thickness of ONO layer 20 is typically about 21 nm or 18 nm in electrical oxide equivalent thickness.

Programming an NROM cell requires increasing the threshold voltage of the cell. Programming an NROM cell typically involves applying a positive voltage to the gate 22, and a positive voltage to the drain while the source is grounded. The programming voltage pulls electrons from the source in a lateral field through channel 12. As the electrons accelerate towards the drain, they eventually achieve sufficient energy to be injected in a vertical field into the nitride layer 20B, this being known as hot electron injection. When the drain and the gate voltages are no longer present, the bottom oxide layer 20A prevents the electrons from moving back in to channel 12.

Hot electron injection is the primary mechanism for programming the NROM cell. Another injection mechanism is known as secondary electron injection. Referring to FIG. 1, as indicated by arrow 3, some channel electrons e₁ (from the primary mechanism) create hole and electron pairs through ionization of valence electrons in channel 12 or the drain (in the illustrated example, diffusion area 18 is the drain). The probability of the ionization is denoted M₁ and it indicates the ratio between the channel current and the hole substrate current.

Due to the positive potential of the drain, generated electron e₂ is collected (arrow 11) by the drain. However, as indicated by arrow 13, hole h₂ accelerates towards the low substrate potential of substrate 14. On the way, another impact ionization may occur, creating another electron-hole pair e₃-h₃ with probability M₂. Hole h₃ is pulled (arrow 15) further into substrate 14 and is no concern. However, electron e₃, called the secondary electron, is accelerated (arrow 17) towards ONO layer 20 where, if it has gained sufficient energy, it is injected into the nitride layer 20B, this event having a probability of T.

The current for secondary injection (I_{g}) is defined as:

I_{g}=Iₛ*M₁*M₂*T

Secondary injection may not be good for all types of memory cells. For NROM cells, enhancing secondary injection may degrade the operation of the cell and may be detrimental.

Erasing all NROM cell requires decreasing the threshold voltage of the cell. Erasing an NROM cell, which is done in the same source/drain direction as programming, typically involves applying a negative voltage to the gate 22 and a positive voltage to the drain, while the source may be floated. The negative gate voltage creates holes in the junction near the drain, typically through band-to-band tunneling. The holes are accelerated by the lateral field near the drain and the ONO layer 20. As the holes accelerate towards the drain, they eventually achieve sufficient energy to be injected into the nitride layer 20B, this being known as tunnel-assisted hot hole injection. When the drain and the gate voltages are no longer present, the bottom oxide layer 20A prevents the holes from moving back in to channel 12.

There may be several problems involved with injecting channel hot electrons (CHE) in the operation of NROM cells. As more electrons are injected into the charge-trapping layer, there is a wider distribution of the electrons in the charge-trapping layer. The wider distribution of electrons is more difficult to erase, and results in a poorer matching of the electrons and holes in the charge-trapping layer. The poorer matching may in turn lead to erase degradation of the cell after many operating cycles, thereby reducing cycling and retention properties of the cell. Furthermore, an increase in primary electrons injected into the charge-trapping layer correspondingly increases the probability of secondary injection. Another disadvantage is that higher currents may be needed to program the cell. This may also reduce retention properties of the cell and increase the probability of secondary injection.

### SUMMARY OF THE INVENTION

The present invention seeks to provide an improved ONO structure for non-volatile memory devices with oxide-nitride-oxide layers, such as, but not limited to, NROM devices. Although the invention is not limited to NROM devices, for the sake of simplicity, the invention will be described hereinbelow with reference to NROM devices. In the present invention, the top oxide layer may be thickened, while the nitride layer and the bottom oxide layer may be thinned.

The increased thickness of the top oxide layer may have several advantages. The thicker top oxide layer may decrease the capacitance between the gate and the charge-trapping nitride layer. The change in charge (ΔQ) stored in the charge-trapping layer is proportional to the product of this capacitance (C) and the change in threshold voltage (ΔV). This means that in order to attain the same increase in threshold voltage (ΔV) as the prior art, fewer electrons need to be injected into the nitride layer. In other words, when programming the cell, fewer electrons need to be injected through the bottom oxide layer into the nitride layer in order to achieve the same increase in the threshold voltage of the cell. Likewise, when erasing the cell, fewer holes need to be injected through the bottom oxide layer into the nitride layer in order to achieve the same decrease in the threshold voltage of the programmed cell.

Some of the advantages of fewer electrons/holes are a narrower electron distribution and a better matching of the electrons and holes in the charge-trapping layer. The better matching results in less erase degradation after many operating cycles, which further results in better cycling and retention properties of the cell. The narrower electron distribution also results in a lower substrate current (Iₛ). The lower Iₛ in turn reduces effects of secondary injection in the NROM cell, as is explained further hereinbelow.

An overall increase in the ONO layer may achieve faster programming/erasing speeds.

There is thus provided in accordance with a preferred embodiment of the present invention a method for forming a non-volatile memory device, the method including forming an oxide-nitride-oxide (ONO) layer over a portion of a substrate, the ONO layer including a bottom oxide layer, a top oxide layer and a nitride layer intermediate the bottom and top oxide layers, and managing movement of at least one of electrons and holes from the substrate towards the ONO layer by controlling a thickness of at least one of the bottom oxide layer, the nitride layer and the top oxide layer, wherein the top oxide layer is at least 1.5 times thicker than the bottom oxide layer.

The method may include forming a thickness of the top oxide layer in a range of approximately 6-20 nm. The nitride layer thickness may be in a range of approximately 1-2 nm. The bottom oxide layer thickness may be in a range of approximately 4-5 nm.

In accordance with a preferred embodiment of the present invention the top oxide layer is at least three times thicker than the nitride layer.

Further in accordance with a preferred embodiment of the present invention the top oxide layer is approximately 3-20 times thicker than the nitride layer.

In accordance with a preferred embodiment of the present invention the top oxide layer is at least 1.5 times thicker than the bottom oxide layer.

Further in accordance with a preferred embodiment of the present invention the top oxide layer is approximately 1.5-4 times thicker than the bottom oxide layer. Still further in accordance with a preferred embodiment of the present invention the top oxide layer is at least half of an overall thickness of the ONO layer.

There is also provided in accordance with a preferred embodiment of the present invention a method for forming a non-volatile memory device, the method including forming an oxide-nitride-oxide (ONO) layer over a portion of a substrate, the ONO layer including a bottom oxide layer, a top oxide layer and a nitride layer intermediate the bottom and top oxide layers, forming a gate over at least a portion of the ONO layer, and decreasing a capacitance between the gate and the nitride layer by controlling a thickness of at least one of the bottom oxide layer, the nitride layer and the top oxide layer, wherein the top oxide layer is at least 1.5 times thicker than the bottom oxide layer.

There is also provided in accordance with a preferred embodiment of the present invention a method for forming a non-volatile memory device, the method including forming an oxide-nitride-oxide (ONO) layer over a portion of a substrate, the ONO layer including a bottom oxide layer, a top oxide layer and a nitride layer intermediate the bottom and top oxide layers, forming a gate over at least a portion of the ONO layer, and increasing a threshold voltage of the non-volatile memory device per number of electrons injectable into the nitride layer by controlling a thickness of at least one of the bottom oxide layer, the nitride layer and the top oxide layer, wherein the top oxide layer is at least 1.5 times thicker than the bottom oxide layer.

There is also provided in accordance with a preferred embodiment of the present invention a method for forming a non-volatile memory device, the method including forming an oxide-nitride-oxide (ONO) layer over a portion of a substrate, the ONO layer including a bottom oxide layer, a top oxide layer and a nitride layer intermediate the bottom and top oxide layers, forming a gate over at least a portion of the ONO layer, and decreasing a threshold voltage of the non-volatile memory device per number of holes injectable into the nitride layer by controlling a thickness of at least one of the bottom oxide layer, the nitride layer and the top oxide layer, wherein the top oxide layer is at least 1.5 times thicker than the bottom oxide layer.

There is also provided in accordance with a preferred embodiment of the present invention a method for forming a non-volatile memory device, the method including forming an oxide-nitride-oxide (ONO) layer over a portion of a substrate, the ONO layer including a bottom oxide layer, a top oxide layer and a nitride layer intermediate the bottom and top oxide layers, forming a gate over at least a portion of the ONO layer, and narrowing a distribution of electrons injectable into the nitride layer by controlling a thickness of at least one of the bottom oxide layer, the nitride layer and the top oxide layer, wherein the top oxide layer is at least 1.5 times thicker than the bottom oxide layer.

There is also provided in accordance with a preferred embodiment of the present invention a method for forming a non-volatile memory device, the method including forming an oxide-nitride-oxide (ONO) layer over a portion of a substrate, the ONO layer including a bottom oxide layer, a top oxide layer and a nitride layer intermediate the bottom and top oxide layers, forming a gate over at least a portion of the ONO layer, and improving a matching of electrons and holes injectable into the nitride layer by controlling a thickness of at least one of the bottom oxide layer, the nitride layer and the top oxide layer, wherein the top oxide layer is at least 1.5 times thicker than the bottom oxide layer.

There is also provided in accordance with a preferred embodiment of the present invention a method for forming a non-volatile memory device, the method including forming an oxide-nitride-oxide (ONO) layer over a portion of a substrate, the ONO layer including a bottom oxide layer, a top oxide layer and a nitride layer intermediate the bottom and top oxide layers, forming a gate over at least a portion of the ONO layer, and enabling a reduction of operational current in the substrate by controlling a thickness of at least one of the bottom oxide layer, the nitride layer and the top oxide layer, wherein the top oxide layer is at least 1.5 times thicker than the bottom oxide layer.

There is also provided in accordance with a preferred embodiment of the present invention a method for operating a non-volatile memory device, the method including providing an oxide-nitride-oxide (ONO) layer over a portion of a substrate, the ONO layer including a bottom oxide layer, a top oxide layer and a nitride layer intermediate the bottom and top oxide layers, applying operating voltages to the non-volatile memory device, and controlling the operating voltages by controlling a thickness of at least one of the bottom oxide layer, the nitride layer and the top oxide layer, wherein the top oxide layer is at least 1.5 times thicker than the bottom oxide layer.

There is also provided in accordance with a preferred embodiment of the present invention a non-volatile memory device including a channel formed in a substrate, two diffusion areas formed one on either side of the channel in the substrate, each diffusion area living a junction with the channel, the channel being adapted to permit movement of primary electrons to at least one of the diffusion areas, and an oxide-nitride-oxide (ONO) layer formed at least over the channel, the ONO layer including a bottom oxide layer, a top oxide layer and a nitride layer intermediate the bottom and top oxide layers, wherein a thickness of at least one of the bottom oxide layer, the nitride layer and the top oxide layer is adapted to manage movement of at least one of electrons and holes from the substrate towards the ONO layer, wherein the top oxide layer is at least 1.5 times thicker than the bottom oxide layer.

### BRIEF DESCRIPTION OF THE DRAWINGS

The present invention will be understood and appreciated more fully from the following detailed description taken in conjunction with the appended drawings in which:

FIG. 1 is a simplified illustration of a typical structure of an NROM non-volatile memory device of the prior art;

FIG. 2 is a simplified illustration of a non-volatile memory device with a modified ONO layer, constructed and operative in accordance with an embodiment of the invention;

FIG. 3 is a simplified graphical illustration of a comparison of programming drain voltages for the memory device of FIG. 2 versus the prior art NROM device of FIG. 1;

FIG. 4 is a simplified graphical illustration of a comparison of erasing speed for the memory device of FIG. 2 versus the prior art NROM device of FIG. 1;

FIG. 5 is a simplified graphical illustration of a comparison of substrate current for the memory device of FIG. 2 versus the prior art NROM device of FIG. 1; and

FIG. 6 is a simplified graphical illustration of a comparison of the erase performance, after many cycles, of the memory device of FIG. 2 versus the prior art NROM device of FIG. 1.

### DETAILED DESCRIPTION OF THE PRESENT INVENTION

Reference is now made to FIG. 2, which illustrates a non-volatile memory device 30, such as an NROM device, constructed and operative in accordance with an embodiment of the invention.

Memory device 30 preferably includes a channel 32 formed in a substrate 34. Two diffusion areas 36 and 38 are preferably formed on either side of channel 32 in substrate 34, each diffusion area having a junction with channel 32. An oxide-nitride-oxide (ONO) layer 40 (i.e., a sandwich of a bottom oxide layer 40A, a nitride layer 40B and a top oxide layer 40C) is preferably formed at least over channel 32, and a polysilicon gate 42 is preferably formed at least over ONO layer 40. Memory device 30 may comprise two separated and separately chargeable areas 43A and 43B in the nitride layer 40B, each chargeable area defining and storing one bit.

In accordance with an embodiment of the invention, the top oxide layer 40C may be thicker than the prior art. Optionally, the nitride layer 40B and the bottom oxide layer 40A may be thinner. One set of possible thicknesses for the layers, although the invention is not limited to these values, is as follows: the top oxide layer 40C—6-20 nm, the nitride layer 40B—1-2 nm, and the bottom oxide layer 40A—4-5 nm. As another example, the top oxide layer 40C made be made thicker such that the overall thickness of ONO layer 40 is greater than the prior art, such as, but not limited to, about 22-30 nm. In terms of ratios, the top oxide layer 40C may be at least three times thicker (e.g., in the range of approximately 3-20 times thicker) than the nitride layer 40B. The top oxide layer 40C may be at least 1.5 times thicker (e.g., in the range of approximately 1.5-4 times thicker) than the bottom oxide layer 40A. The top oxide layer 40C may comprise at least half of the overall thickness of ONO layer 40.

The modification in the layer thickness may be constrained by certain limitations. For example, the minimum thickness of the bottom oxide layer 40A may be constrained by a minimum requirement for protection against direct tunneling current from nitride layer 40B to substrate 34. The minimum thickness of the nitride layer 40B may be constrained by a minimum requirement for charge trapping capability in ONO layer 40. The thickness of the top oxide layer 40C may be dictated by functionality requirements, such as, but not limited to, threshold voltage, for example.

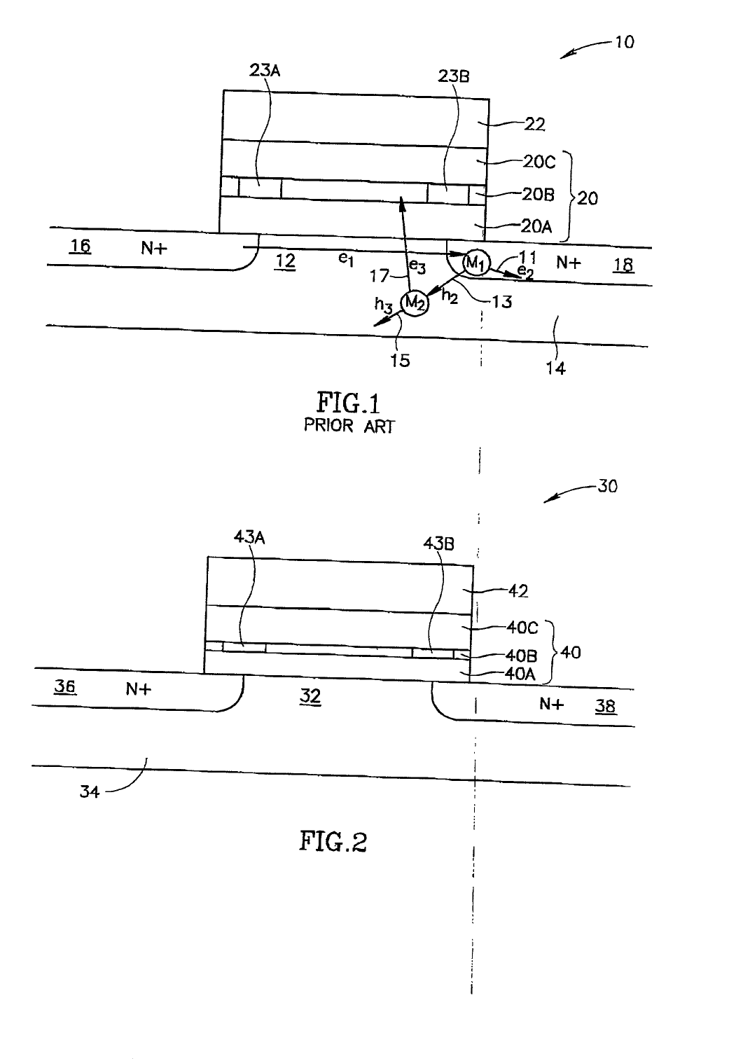

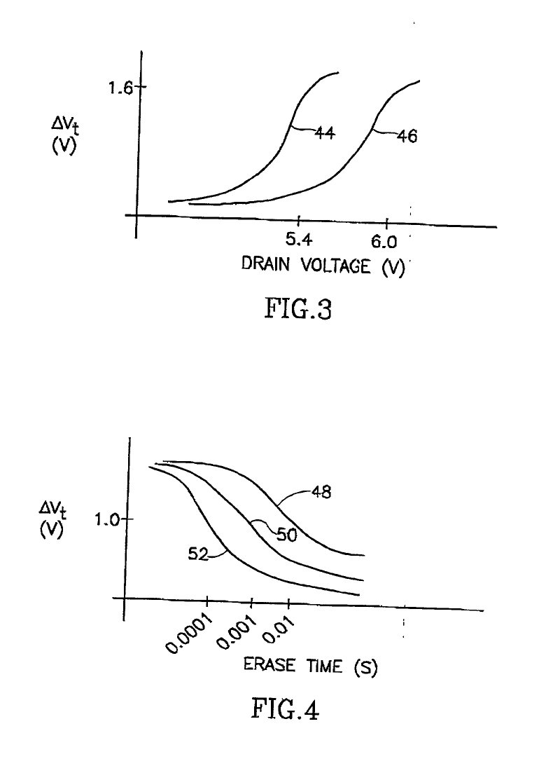

Reference is now made to FIG. 3, which is a graphical illustration of a comparison of programming drain voltages for the memory device 30 versus the prior art NROM device 10 of FIG. 1 in a mini-array configuration. The thicker ONO stack (ONO layer 40) may result in smaller programming voltages, which means that lower bit line voltages may be used to program memory device 30 as opposed to the prior art NROM device 10. FIG. 3 illustrates programming the NROM devices with a gate voltage of 9 V for 2 μs, although the invention is not limited to these values. As seen in FIG. 3, in order to program the cell with an increase of 1.6 V in the threshold voltage, the memory device 30 of the present invention may require a drain voltage of only 5.4 V (graph 44) as opposed to the prior art NROM device 10 which may require a drain voltage of 6.0 V (graph 46). Thus the present invention reduces the programming voltages that are required to achieve a give threshold voltage, and increases the programming speed. Reference is now made to FIG. 4, which is a graphical illustration of a comparison of erasing speed for the memory device 30 versus the prior art NROM device 10 of FIG. 1, wherein the overall thickness of the ONO layer of the memory device 30 is greater than the prior art NROM device 10. Curve 52 of FIG. 4 illustrates erasing the memory device 10 of the prior art with a gate voltage of −3 V and a drain voltage of 6 V for 250 μs. Curve 50 of FIG. 4 illustrates erasing the NROM device 30 of the present invention with the same negative gate voltage of −3 V, and the same drain voltage of 6 V, for 250 μs, although the invention is not limited to these values. It is seen that for the same negative gate voltage, it may take about 10 times longer to erase the NROM device 30 of the present invention than to erase the memory device 10 of the prior art. However, for these erasure voltages, the vertical field of the memory device 10 of the prior art is different than the vertical field of the NROM device 30 of the present invention. A comparison of the two devices with equal vertical fields may be seen in curve 48 of FIG. 4. Curve 48 illustrates erasing the NROM device 10 of the prior art with a gate voltage of −1.125 V and positive drain voltage of 6 V for 250 μs, which results in substantially the same vertical field associated with curve 50. It is seen that for the same vertical field, the NROM device 30 of the present invention may be erased about 10 times faster than the memory device 10 of the prior art.

Fewer holes need to be injected through the bottom oxide layer 40A into the nitride layer 40B in order to achieve the same decrease in the threshold voltage of the memory device 30, thereby achieving the faster erase speed.

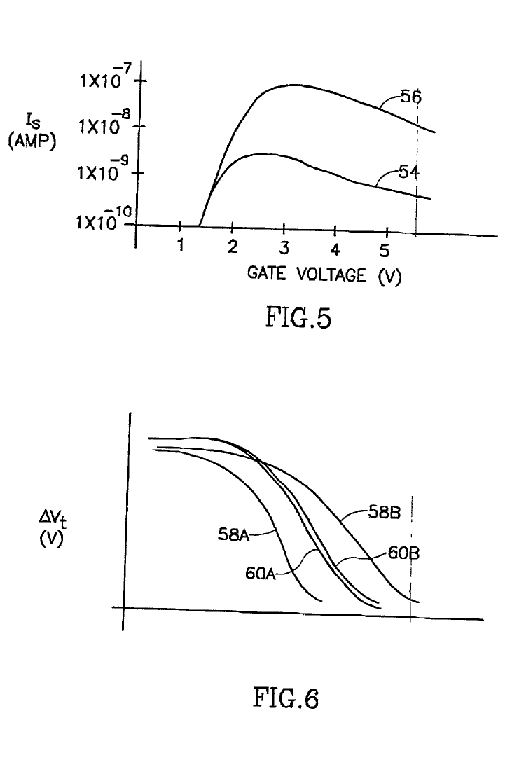

Reference is now made to FIG. 5, which is a graphical illustration of a comparison of substrate current (Iₛ) for the programmed memory device 30 versus the prior art programmed NROM device 10 of FIG. 1. Curve 54 of FIG. 5 illustrates Iₛ versus gate voltage for the programmed memory device 30 of the present invention. In contrast, curve 56 of FIG. 5 illustrates Iₛ versus gate voltage for the programmed NROM device 10 of the prior art. It is seen that for the same gate voltages, the Iₛ for the programmed memory device 30 of the present invention is lower by about an order of magnitude than the Iₛ for the programmed NROM device 10 of the prior art. The lower Iₛ in turn reduces effects of secondary injection in the memory device 30.

Reference is now made to FIG. 6, which is a graphical illustration of a comparison of the erase performance, after many cycles, of the memory device 30 versus the prior art NROM device 10 of FIG. 1. Curves 59A and 58B of FIG. 6 illustrate degradation in erase of the NROM device 10 of the prior art after about 10,000 cycles. It is noted that there is a degradation of over 1 V. The degradation may be due to a wide electron distribution and the secondary injection mechanism. In contrast, Curves 60A and 60B of FIG. 6 illustrate the degradation in erase of the memory device 30 of the present invention. Virtually no degradation is seen after about 10,000 cycles. The better matching results in better retention and cycling properties of the memory device 30.

It will be appreciated by persons skilled in the art that the present invention is not limited by what has been particularly shown and described herein above. Rather the scope of the invention is defined by the claims that follow:

What is claimed is:

1. A method for forming a non-volatile memory device, the method comprising:
forming an oxide-nitride-oxide (ONO) layer over a portion of a substrate, said ONO layer comprising a bottom oxide layer, a top oxide layer and a nitride layer intermediate said bottom and top oxide layers; and
managing movement of at least one of electrons and holes from said substrate towards said ONO layer by controlling a thickness of at least one of said bottom oxide layer, said nitride layer and said top oxide layer, wherein said top oxide layer is at least 1.5 times thicker than said bottom oxide layer.

2. The method according to claim 1 wherein said managing comprises forming a thickness of said top oxide layer in a range of approximately 6-20 nm.

3. The method according to claim 1 wherein said managing comprises forming a thickness of said nitride layer in a range of approximately 1-2 nm.

4. The method according to claim 1 wherein said managing comprises forming a thickness of said bottom oxide layer in a range of approximately 4-5 nm.

5. The method according to claim 1 wherein said managing comprises forming said top oxide layer to be at least three times thicker than said nitride layer.

6. The method according to claim 1 wherein said managing comprises forming said top oxide layer to be approximately 3-20 times thicker than said nitride layer.

7. The method according to claim 1 wherein said managing comprises forming said top oxide layer to be at least 1.5 times thicker than said bottom oxide layer.

8. The method according to claim 1 wherein said managing comprises forming said top oxide layer to be approximately 1.5-4 times thicker than said bottom oxide layer.

9. The method according to claim 1 wherein said managing comprises forming said top oxide layer to be at least half of an overall thickness of said ONO layer.

10. A method for forming a non-volatile memory device, the method comprising:
forming an oxide-nitride-oxide (ONO) layer over a portion of a substrate, said ONO layer comprising a bottom oxide layer, a top oxide layer and a nitride layer intermediate said bottom and top oxide layers;
forming a gate over at least a portion of said ONO layer; and
decreasing a capacitance between said gate and said nitride layer by controlling a thickness of at least one of said bottom oxide layer, said nitride layer and said top oxide layer, wherein said top oxide layer is at least 1.5 times thicker than said bottom oxide layer.

11. A method for forming a non-volatile memory device, the method comprising:
forming an oxide-nitride-oxide (ONO) layer over a portion of a substrate, said ONO layer comprising a bottom oxide layer, a top oxide layer and a nitride layer intermediate said bottom and top oxide layers;
forming a gate over at least a portion of said ONO layer; and
increasing a threshold voltage of said non-volatile memory device per number of electrons injectable into said nitride layer by controlling a thickness of at least one of said bottom oxide layer, said nitride layer and said top oxide layer, wherein said top oxide layer is at least 1.5 times thicker than said bottom oxide layer.

12. A method for forming a non-volatile memory device, the method comprising:
forming an oxide-nitride-oxide (ONO) layer over a portion of a substrate, said ONO layer comprising a bottom oxide layer, a top oxide layer and a nitride layer intermediate said bottom and top oxide layers;
forming a gate over at least a portion of said ONO layer; and
decreasing a threshold voltage of said non-volatile memory device per number of holes injectable into said nitride layer by controlling a thickness of at least one of said bottom oxide layer, said nitride layer and said top oxide layer, wherein said top oxide layer is at least 1.5 times thicker than said bottom oxide layer.

13. A method for forming a non-volatile memory device, the method comprising: forming an oxide-nitride-oxide (ONO) layer over a portion of a substrate, said ONO layer comprising a bottom oxide layer, a top oxide layer and a nitride layer intermediate said bottom and top oxide layers;
forming a gate over at least a portion of said ONO layer; and
narrowing a distribution of electrons injectable into said nitride layer by controlling a thickness of at least one of said bottom oxide layer, said nitride layer and said top oxide layer, wherein said top oxide layer is at least 1.5 times thicker than said bottom oxide layer.

14. A method for forming a non-volatile memory device, the method comprising:
forming an oxide-nitride-oxide (ONO) layer over a portion of a substrate, said ONO layer comprising a bottom oxide layer, a top oxide layer and a nitride layer intermediate said bottom and top oxide layers;
forming a gate over at least a portion of said ONO layer; and
improving a matching of electrons and holes injectable into said nitride layer by controlling a thickness of at least one of said bottom oxide layer, said nitride layer and said top oxide layer, wherein said top oxide layer is at least 1.5 times thicker than said bottom oxide layer.

15. A method for forming a non-volatile memory device, the method comprising:
forming an oxide-nitride-oxide (ONO) layer over a portion of a substrate, said ONO layer comprising a bottom oxide layer, a top oxide layer and a nitride layer intermediate said bottom and top oxide layers;
forming a gate over at least a portion of said ONO layer; and
enabling a reduction of operational current in said substrate by controlling a thickness of at least one of said bottom oxide layer, said nitride layer and said top oxide layer, wherein said top oxide layer is at least 1.5 times thicker than said bottom oxide layer.

16. A method for operating a non-volatile memory device, the method comprising:
providing an oxide-nitride-oxide (ONO) layer over a portion of a substrate, said ONO layer comprising a bottom oxide layer, a top oxide layer and a nitride layer intermediate said bottom and top oxide layers;
applying operating voltages to said non-volatile memory device; and
controlling said operating voltages by controlling a thickness of at least one of said bottom oxide layer, said nitride layer and said top oxide layer, wherein said top oxide layer is at least 1.5 times thicker than said bottom oxide layer.

17. A non-volatile memory device comprising:
a channel formed in a substrate;
two diffusion areas formed one on either side of said channel in said substrate, each diffusion area having a junction with said channel, said channel being adapted to permit movement of primary electrons to at least one of said diffusion areas; and
an oxide-nitride-oxide (ONO) layer formed at least over said channel, said ONO layer comprising a bottom oxide layer, a top oxide layer and a nitride layer intermediate said bottom and top oxide layers;
wherein a thickness of at least one of said bottom oxide layer, said nitride layer and said top oxide layer is adapted to manage movement of at least one of electrons and holes from said substrate towards said ONO layer, wherein said top oxide layer is at least 1.5 times thicker than said bottom oxide layer.

18. The device according to claim 17 wherein the thickness of said top oxide layer is approximately 6-20 nm.

19. The device according to claim 17 wherein the thickness of said nitride layer is approximately 1-2 nm.

20. The device according to claim 17 wherein the thickness of said bottom oxide layer is approximately 4-5 nm.

21. The device according to claim 17 wherein said top oxide layer is at least three times thicker than said nitride layer.

22. The device according to claim 17 wherein said top oxide layer is approximately 3-20 times thicker than said nitride layer.

23. The device according to claim 17 wherein said top oxide layer is approximately 1.5-4 times thicker than said bottom oxide layer.

24. The device according to claim 17 wherein said top oxide layer comprises at least half of an overall thickness of said ONO layer.
